(19) United States
(12) Patent Application Publication
(10) Pub. No.: US 2011/0002106 A1
(43) Pub. Date: Jan. 6, 2011

(54) Miniature Waterproof Electronic Device Enclosure

(75) Inventors: John Bentley, Santa Clara, CA (US); Jeetendra Jangle, Fremont, CA (US)

Correspondence Address: Law Office of Brian Short, P.O. Box 641867, San Jose, CA, 95164-1867, US

(73) Assignee: WELLCORE CORPORATION, San Jose, CA (US)

(21) Appl. No.: 12/823,280

(22) Filed: Jun. 25, 2010

Related U.S. Application Data
(60) Provisional application No. 61/222,308, filed on Jul. 1, 2009.

(51) Int. Cl. H05K 5/00; H01R 13/46; H05K 5/06; B21D 39/00; H05K 13/00

(52) U.S. Cl. 361/752; 174/50; 174/520; 174/50.6; 29/524.1; 29/592.1

(57) ABSTRACT

Embodiments of an electronic device apparatus are disclosed. One apparatus includes a housing structure having an inner surface and an outer surface. A plurality of electrical feed-throughs extend through the housing structure from the outer surface to the inner surface. Each of the feed-throughs includes an outer surface cross-section and an inner surface cross-section and a pass through cross-section. The pass through cross-section of the feed-through is located at a portion of the feed-through that extends through the housing structure. The outer surface cross-section is located where the feed-through is exposed on the outer surface, and the inner surface cross-section located where the feed-through is exposed on the inner surface. The feed-through cross-section is less than the outer surface cross-section and the inner surface cross-section.

### RELATED APPLICATIONS

This patent application claims priority to U.S. provisional patent application Ser. No. 61/222,308 filed on Jul. 1, 2009, which is incorporated by reference.

### FIELD OF THE DESCRIBED EMBODIMENTS

The described embodiments relate generally to electronic device packaging. More specifically, the described embodiments relate to an apparatus and design for a water proof electronic device package.

### BACKGROUND

Mobile devices have become ubiquitous over the past two decades. From cell phones to MP3 players to hearing aids to digital cameras to Nintendo Gameboys, it is hard to find any person, young or old, that is not a heavy user of such devices. In recent years, the world of wireless sensor devices has witnessed rapid growth, one that is poised to enjoy rapid growth in the foreseeable future.

One class of wireless sensors that is gaining popularity is wearable motion sensing devices. These units, carried or worn by people on their bodies, have the ability to detect changes in acceleration, spatial orientation, gravitational force and angular momentum, and thereby provide a measure of the types of motion that are occurring on the human beings that they are tethered to. As a general rule, such devices are either affixed to the wrist via a wristband, to the upper arm through an armband, to a shoe via a shoe clip, to an ankle via an ankle strap, or simply clipped onto a garment that the person is wearing.

Through wearing these sensors, the motion of the person is registered, and can thereafter be subjected to motion analysis regarding the activities of the person. Such units typically detect human motions at the point where they are tethered to the body, and thereafter use those motions as being representative of the entire person.

These personal electronic devices continue to increase in complexity and decrease in size to the point where daily human motion-related wellness can be monitored. However, a device that monitors daily motion of a person must have several features including: a motion sensor, a means to wirelessly transmit the motion data, a wired digital interface for control, mechanical switches to enable features, method of charging internal battery, and it must all be enclosed in a waterproof enclosure.

It is desirable to have a waterproof electronic device package that protects internal electronic of the package while the electronic device package is worn (attached to) by a user during normal daily activities of the user.

### SUMMARY OF THE DESCRIBED EMBODIMENTS

An embodiment includes an electronic device apparatus. The apparatus includes a housing structure having an inner surface and an outer surface. A plurality of electrical feed-throughs extend through the housing structure from the outer surface to the inner surface. Each of the feed-throughs includes an outer surface cross-section and an inner surface cross-section and a pass through cross-section. The pass through cross-section of the feed-through is located at a portion of the feed-through that extends through the housing structure. The outer surface cross-section is located where the feed-through is exposed on the outer surface, and the inner surface cross-section located where the feed-through is exposed on the inner surface. The feed-through cross-section is less than the outer surface cross-section and the inner surface cross-section.

Other aspects and advantages of the described embodiments will become apparent from the following detailed description, taken in conjunction with the accompanying drawings, illustrating by way of example the principles of the described embodiments.

### BRIEF DESCRIPTION OF THE DRAWINGS

FIG. 1 shows an example of a motion detection sensor that can be electrically interfaced with a base unit.

FIG. 2 shows an example of a cross-sectional view of an example of an electrical contact of the electronic device package that includes an embodiment of an electrical feed-through.

FIG. 3 shows an example of a cross-sectional view of an example of an electrical contact of the electronic device package that includes another embodiment of an electrical feed-through.

FIG. 4 shows an example of a cross-sectional view of another example of an electrical contact of the electronic device package.

FIG. 5 is a flow chart that includes steps of an example of a method of forming electrical feed-throughs.

FIG. 6 is a flow chart that includes steps of an example of a method of forming an electronic device package that includes electrical feed-throughs that are electrically connected to a controller board of the electronic device.

### DETAILED DESCRIPTION OF INVENTION

The described embodiments include an electronic device package that can include, for example, motion sensing electronics. For one embodiment, the package includes a plastic injection-molded enclosure. The enclosure provides a waterproof package that can include an embedded radio. Electrical feed through(s) in the enclosure provide conductive paths for charging of a battery within the enclosure, and for programming electronics within the enclosure, while maintaining a water seal.

The packaging is waterproof to the extent necessary to protect the internal device (electronics) from daily living activities such as bathing, a shower, or accidental emersion in a sink or clothes washing machine cycle. As mentioned, embodiments of the packaging contain an embedded radio for continuous communication of the state of motion of a person, piece of equipment, or any other item where tracking of its physical orientation versus time within range of a receiving base can be observed and recorded. While the described embodiments may be for a motion sensing device, it is to be understood that the electrical feed-through embodiments described, and the water-proof packaging described, can be utilized for electronic packaging in general.

The electrical feed through(s) in the enclosure allows for charging of the internal battery and digital interface signals to pass through the enclosure while maintaining a water seal. Embodiments of the enclosure additionally provide the ability to allow light from internal LED's to provide visual status of the device. Embodiments of the enclosure allow for transmission of sound signals from inside the device to aid in location of a lost device or to provide audible indication of the state of the device. Embodiments include an electrical switch interface to enable a feature or function without impact to the water seal.

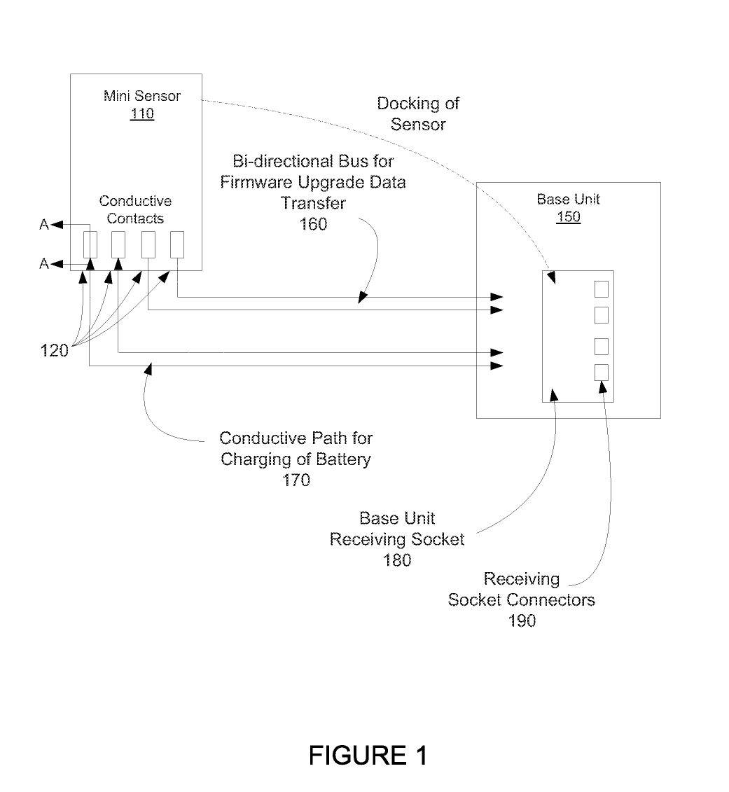

FIGS. 1-4 show embodiments of enclosures that provide possible methods of implementing the electrical contact feed-throughs of the water proof electronic apparatus. As described, embodiments of the electronic apparatus include a water proof mobile electronic device that monitors the motion of a user that the mobile electronic device is attached to.

FIG. 1 shows an example of the mobile electronic device (mini-sensor) 110 having four electrical contacts 120 (clearly, the number of electrical contacts is optional). The mobile electronic device 110 can be placed within, for example, a cradle (base unit) 150 for re-charging of a battery within the mobile electronic device, and for the transfer of information between the mobile electronic device 110 and the cradle 150. That is, the electrical contact points 120 of the mobile electronic device 110 and receiving socket connectors 190 the cradle 150 provide conductive paths 160, 170 when the mobile electronic device 110 is placed within a base unit receiving socket 180 of the cradle 150. The conductive paths 160, 170 allow electronic circuitry within, for example, the cradle 150 to both charge the battery within the mobile electronic device, and provide a communications path to either upload or download information to/from the mobile electronic device.

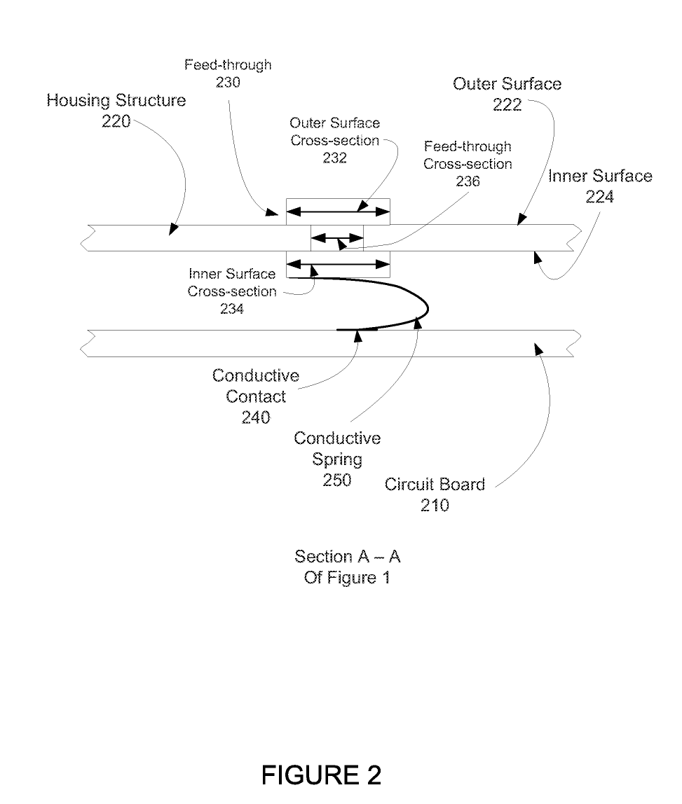

FIG. 2 shows a cross-sectional view (A-A) of an example of an implementation of the electrical feed-though 230 of the electronic device of FIG. 1. The electrical feed-through 230 passes through the housing structure 220 (which can be, for example, a plastic enclosure) of the mobile electronic device. Additionally FIG. 2 shows an embodiment of an electrical connection 250 (conductive spring contact) between the feed through 230 and an electrical contact 240 of a printed circuit board 210 (located within) of the mobile electronic device. The feed-through 230 is electrically conductive while the housing structure 220 is electrically non-conductive.

As shown the feed-through 230 includes an outer surface cross-section 232, a feed-through cross-section 236 and an inner surface cross-section 234. The outer area of the feed-through 230 having the outer surface cross-section 232 is located adjacent to an outer surface 222 of the housing structure 220. The feed-through area of the feed-through 230 having the feed-through cross-section 236 is located within the housing structure 220. The inner area of the feed-through 230 having the inner surface cross-section 234 is located adjacent to the inner surface 224 of the housing structure 220.

As shown, the outer surface cross-section 232 and the inner surface cross-section 234 are both greater than the feed-through cross section 236. If properly formed, the shape of the feed-through 230 ensures that the housing structure is water proof, while still allowing signals and/or power supply signals to pass through the housing structure. The feed-through 230 physically contacts the housing structure 220 at multiple surfaces, ensuring that the feed-through 230/housing structure 220 combination is water proof. That is, embodiments include the inner area, the feed-through area and the outer area physically contacting the housing structure 220.

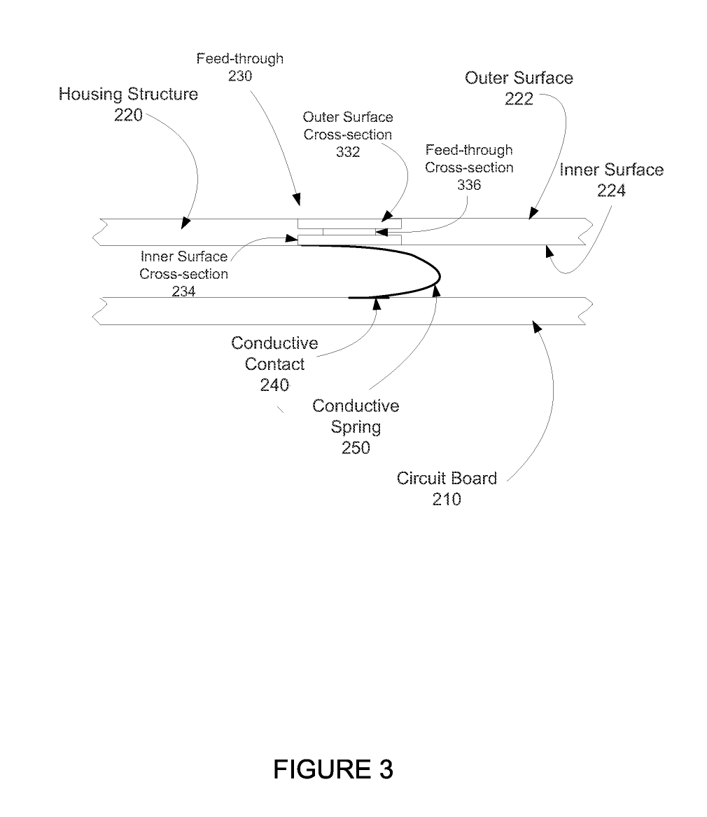

FIG. 3 shows an example of a cross-sectional view of an example of an electrical contact of the electronic device (for example, a motion detection sensor) that includes another embodiment of an electrical feed-through. This embodiment of the feed-through 230 includes the outer area of the feed-through 230 having the outer surface cross-section 232 being substantially flush with the outer surface 222 of the housing structure 220. Additionally, the inner area of the feed-through 230 having the inner surface cross-section 234 is flush with the inner surface 224 of the housing structure 220. Clearly, combinations of FIGS. 2 and 3 can be employed. That is embodiments include either or both of the inner area or the outer area being (or not being) flush with either the inner surface 224 or the outer surface 222.

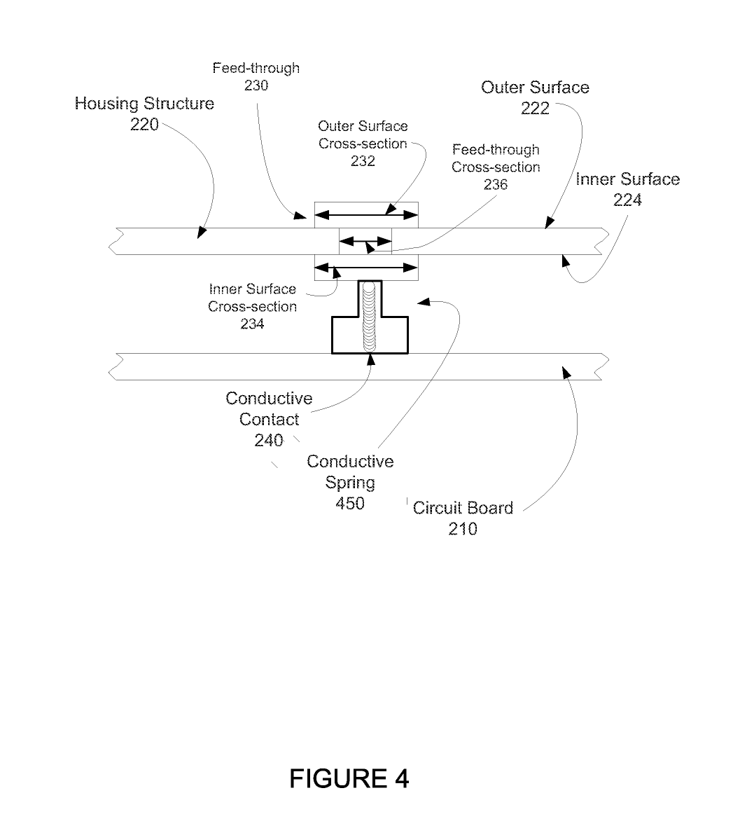

FIG. 4 shows an example of a cross-sectional view of another example of an electrical contact of the electronic device (for example, a motion detection sensor). The conductive spring 450 of FIG. 4 is different than the conductive spring 250 of FIGS. 2, 3. It is to be understood that other embodiments of the conductive spring can be utilized as well. The conductive spring is provided as one way in which an electrical connection can be made between the conductive feed-through 230 and a conductive contact 240 of the circuit board 210 located within the water proof housing of the electronic device housing structure 220. The conductive spring 450 includes an internal spring that urges the conductive spring 450 to make electrical contact with the conductive feed-through 230. The conductive spring enables the electrical connection to be formed when pieces (external housing) of the electronic device (for example, a motion detection sensor) are attached as described later.

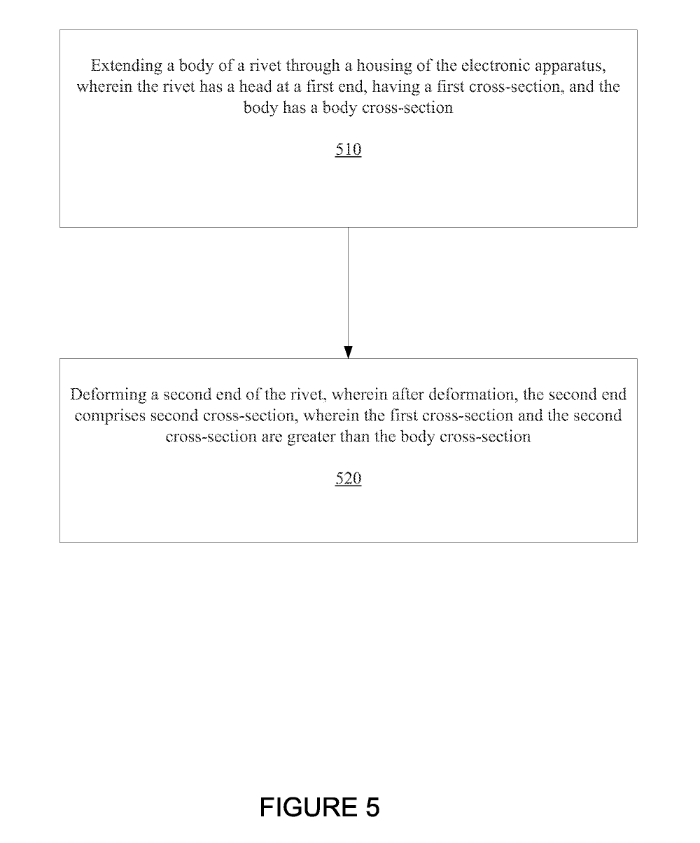

FIG. 5 is a flow chart that includes steps of an example of a method of forming electrical feed-throughs of an electronic apparatus. A first step 510 includes extending a body of a rivet through a housing of the electronic apparatus, wherein the rivet has a head at a first end, having a first cross-section (equivalent to either the previously described inner surface cross-section or the outer surface cross-section), and the body has a body cross-section (equivalent to the previously described feed-through cross-section). A second step 520 includes deforming a second end of the rivet, wherein after deformation, the second end comprises second cross-section (equivalent to the other of the previously described inner surface cross-section or the outer surface cross-section), wherein the first cross-section and the second cross-section are greater than the body cross-section.

The deformation of the rivet forms a water proof electrical connection through the housing of the electronic apparatus. Similar to previously described embodiments, a controller circuit board can be attached to the housing, wherein a spring conductor provides an electrical connection between the rivet and the controller circuit board.

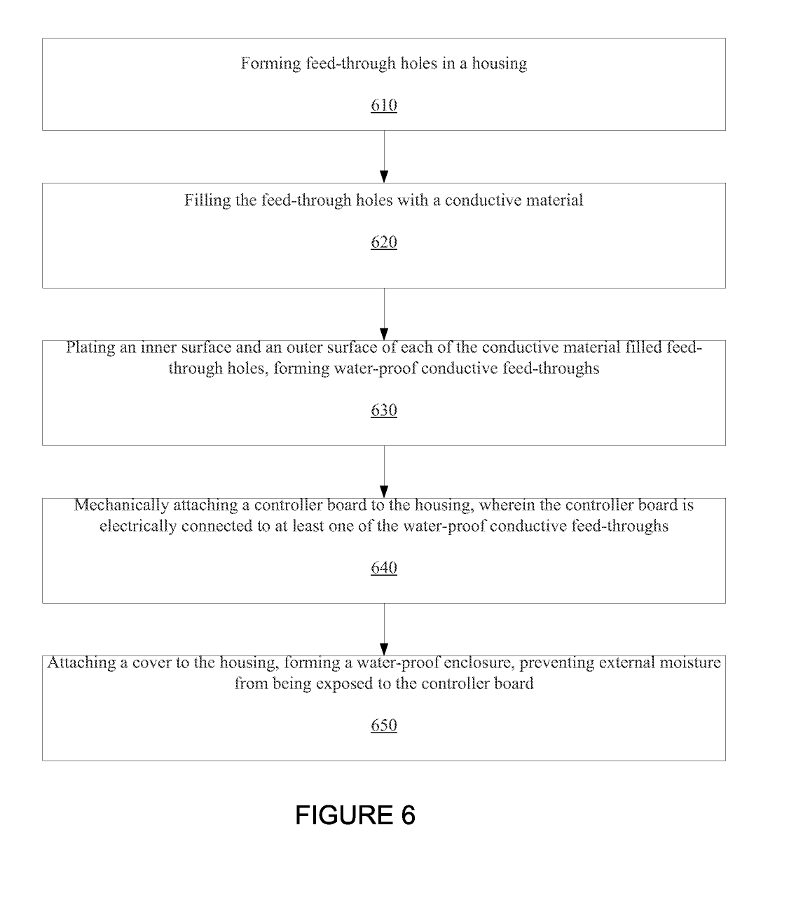

FIG. 6 is a flow chart that includes steps of an example of a method of forming an electronic device that includes electrical feed-throughs that are electrically connected to a controller board of the electronic device. A first step 610 includes forming feed-through holes in the housing of the electronic device. A second step 620 includes filling the feed-through holes with a conductive material. A third step 630 includes plating an inner surface and an outer surface of each of the conductive material filled feed-through holes, forming water-proof conductive feed-throughs. A fourth step 640 includes mechanically attaching a controller board to the housing, wherein the controller board is electrically connected to at least one of the water-proof conductive feed-throughs. A fifth step 650 includes attaching a cover to the housing, forming a water-proof enclosure, preventing external moisture from being exposed to the controller board. Additionally, a battery can be mechanically attached to the housing, wherein the battery is electrically connected to at least one of the water-proof conductive feed-throughs.

The first method of implementing the electrical feed-throughs includes a plated-through hole with contact areas on each side of the plastic enclosure larger than the hole. This allows a spring pressure contact on both sides allowing electrical signals to pass through the enclosure while maintaining the water seal required. Typically, a cross-section of the plated ends on each side of the housing is greater than the cross-section of the conductor passing through the hole in the housing. The plated ends of the feed throughs provide a water-tight seal.

An alternate way of manufacturing the electrical feed through is with a metal insert similar to a mechanical structural rivet which can be inserted and the inserted end deformed to permanently attach the rivet to the plastic case while maintaining the water seal. Before being inserted through a hole in the housing, the rivet includes an end that has a head having a cross-section that is greater than the rest of the rivet. The rivet is inserted through a hole in the housing of the mobile electronic device. The non-head end of the rivet extends through the hole after insertion through the hole. The non-head end is then deformed so that after deformation, the deformed end has a cross-section that is greater than the body of the rivet that is extended through the hole. The deformation process forms a water-tight seal of the hole.

The manufacturing method used can selected by evaluating the sealing effectiveness and cost associated with the chosen method.

Generally, the housing of the electronic device includes two halves which are sealed after formation of the electrical feed throughs, and after attachment of the circuit board that is to reside within the electronic device. The method of sealing the two halves of the plastic enclosure can be done with ultrasonic or thermal welding techniques. There is no need to open the enclosure after final assembly so either method of permanent sealing can be employed.

Although specific embodiments have been described and illustrated, the embodiments are not to be limited to the specific forms or arrangements of parts so described and illustrated. The embodiments are limited only by the appended claims.

What is claimed:

1. An electronic device apparatus, comprising:
a housing structure comprising an inner surface and an outer surface;
a plurality of electrical feed-throughs extending through the housing structure from the outer surface to the inner surface;
each feed-through comprising an outer surface cross-section and an inner surface cross-section and a pass through cross-section, wherein the feed-through has the pass through cross-section located at a portion of the feed-through that extends through the housing structure, the outer surface cross-section is located where the feed-through is exposed on the outer surface, and the inner surface cross-section is located where the feed-through is exposed on the inner surface, wherein the feed-through cross-section is less than the outer surface cross-section and the inner surface cross-section.

2. The apparatus of claim 1, wherein each of the plurality of feed-throughs is water proof due to the outer surface cross-section and the inner surface cross-section being greater than the feed-through cross-section.

3. The apparatus of claim 1, further comprising a controller circuit board, the controller circuit board electrically connected to at least one of the electrical feed-throughs through an electrical spring connector.

4. The apparatus of claim 3, wherein the controller circuit board is ensconced within the housing structure, and wherein the housing provides a water-proof enclosure, preventing the controller circuit board from being exposed to external moisture.

5. The apparatus of claim 1, further comprising a controller circuit board and a battery, the controller circuit board electrically connected to at least one of the electrical feed-throughs through an electrical spring connector, and the battery electrically connected to at least one of the electrical feed-throughs.

6. The apparatus of claim 3, wherein the controller circuit board and the battery are ensconced within the housing structure, and wherein the housing provides a water-proof enclosure, preventing the controller circuit board and the battery from being exposed to external moisture.

7. The apparatus of claim 1, wherein the electronic device apparatus is adaptable to being received by an electronic cradle, wherein the electronic cradle charges the electronic device apparatus through the plurality of electrical feed-throughs.

8. The apparatus of claims 1, wherein the electronic device apparatus is adaptable to being received by an electronic cradle, wherein the electronic cradle provides digital signals for providing control of the electronic device apparatus, the digital signals being provided to the electronic apparatus through the plurality of electrical feed-throughs.

9. The apparatus of claim 1, wherein each feed-through comprises an electrically conductive plated via.

10. The apparatus of claim 1, wherein the housing structure is electrically non-conductive and each of the feed-throughs is electrically conductive.

11. A method of forming electrical feed-throughs of an electronic apparatus, comprising:
extending a body of a rivet through a housing of the electronic apparatus, wherein the rivet has a head at a first end, having a first cross-section, and the body has a body cross-section;
deforming a second end of the rivet, wherein after deformation, the second end comprises second cross-section, wherein the first cross-section and the second cross-section are greater than the body cross-section.

12. The method of claim 11, wherein the rivet forms a water proof electrical connection through the housing of the electronic apparatus.

13. The method of claim 11, further comprising attaching a controller circuit board to the housing, wherein a spring conductor provides an electrical connection between the rivet and the controller circuit board.

14. A method of forming a portable sensor device, comprising:
forming feed-through holes in a housing;
filling the feed-through hole's with a conductive material;
plating an inner surface and an outer surface of each of the conductive material filled feed-through holes, forming water-proof conductive feed-throughs;
mechanically attaching a controller board to the housing, wherein the controller board is electrically connected to at least one of the water-proof conductive feed-throughs;
attaching a cover to the housing, forming a water-proof enclosure, preventing external moisture from being exposed to the controller board.

15. The method of claim 14, further comprising mechanically attaching a battery to the housing, wherein the battery is electrically connected to at least one of the water-proof conductive feed-throughs.
